(19) United States
(12) Patent Application Publication
(10) Pub. No.: US 2021/0112669 A1
(43) Pub. Date: Apr. 15, 2021

(54) CONDUCTIVE SLURRY AND PLATING METHOD USING THE SAME

(71) Applicant: National Taiwan University of Science and Technology, Taipei (TW)

(72) Inventors: CHIH-WEI CHIU, Taipei (TW); CHEN-YANG HUANG, Taipei (TW)

(21) Appl. No.: 16/597,201

(22) Filed: Oct. 9, 2019

(51) Int. Cl. H05K 3/42; C25D 5/02; C25D 5/34; C25D 7/00

(52) U.S. Cl. CPC H05K 3/425; H05K 3/422; C25D 5/02; H05K 2203/0783; C25D 7/00; H05K 2203/1438; H05K 2203/072; C25D 5/34

(57) ABSTRACT

A conductive slurry for plating comprises a carbon material, a dispersant, a binder, and a solvent. The carbon material, the dispersant and the binder are uniformly mixed in the solvent. The weight percentage of the carbon material is between 0.1% and 1%. The carbon material comprises a carbon nanotube, graphene, or a combination thereof. A plating method for a circuit board, which utilizes the conductive slurry, is also disclosed. The circuit board comprises at least a through hole. The plating method comprises a coating step, a first cleaning step, a first drying step, a first micro-etching step, a second cleaning step, an anti-oxidation step, a third cleaning step, a plating step, and a second drying step.

### BACKGROUND

### Technology Field

The present disclosure relates to a conductive slurry for plating and a method for plating a circuit board, in particular for plating a circuit board having at least one through hole, by utilizing the conductive slurry.

### Description of Related Art

The circuit board is an electronic component comprising an insulating substrate and a plurality of conductive wires formed on the insulating substrate. In the manufacturing process of the circuit board, the substrate is drilled to generate a through hole, and then a conductive material is formed on the non-conductive material of the wall of the through hole for conducting the metal layers of the circuit board. For example, the conductive material can be a layer of copper formed by plating.

Forming the conductive material on the wall of the through hole of the circuit board is a critical technology in the manufacturing of circuit board. Generally, there are two methods for forming the conductive material on the wall of the through hole of the circuit board. The first method is to deposit a layer of copper on the wall of the through hole by plating through hole (PTH). However, the PTH solution contains various environmentally hazardous chemicals such as EDTA, NTA, EDTP and formaldehyde, which is easily carcinogenic, resulting in higher cost of wastewater treatment. Besides, the copper plating layer made by PTH has poor mechanical properties.

The other method is to perform a plating process with the commercial conductive paste, which is a suspension of a conductive material (e.g. carbon black or graphite) suspending in water. Since the conductive material has poor hydrophilicity, the suspension is unstable and is prone to coagulation, which affects the performance thereof. In addition, the process of plating using the conductive paste is complicated. For example, before the plating step, the plating process comprises the pretreatment steps of conditioning, washing, applying conductive paste, developing, washing, drying, micro-etching, washing, anti-oxidation, washing, and drying. These steps are time consuming, and the conductivity and adhesion of the plated metal layer still need to be improved.

Therefore, it is desired to provide a conductive slurry and a plating method that does not need the complicated plating steps, and can prevent to generate the environmentally hazardous chemicals and improve the conductivity and adhesion of the plated metal layer.

### SUMMARY

In view of the foregoing, an objective of this disclosure is to provide a conductive slurry and a plating method that can improve the conductivity and adhesion of the plated metal layer, simplify the plating process, and decrease the manufacturing cost.

To achieve the above objective, the present disclosure provides a conductive slurry for plating, which comprises a carbon material, a dispersant, a binder, and a solvent. The carbon material, the dispersant and the binder are uniformly mixed in the solvent. The weight percentage of the carbon material is between 0.1% and 1%, and the carbon material comprises a carbon nanotube, graphene, or a combination thereof.

In one embodiment, the weight percentage of the dispersant is between 0.1% and 25%.

In one embodiment, the weight percentage of the dispersant is between 0.3% and 1%.

In one embodiment, the weight percentage of the binder is between 0.1% and 25%.

In one embodiment, the weight percentage of the binder is between 0.3% and 1%.

In one embodiment, the dispersant comprises polyvinyl alcohol, waterborne polyurethane colloid, polyvinyl acetate, polyvinyl ether, polyvinyl chloride, epoxy resin, cresol novolac resin, phenol novolac resin, epichlorohydrin resin, bisphenol resin, phenolic resin, or a combination thereof.

In one embodiment, the binder comprises tetrasaccharide, pentose, hexose, maltose, fructose, lactose, cellulose acetate, nitrocellulose, methyl cellulose, carboxymethyl cellulose, glucomannan (d-gluco-d-mannans), milk glucomannan (d-galacto-d-gluco-d-mannans), alkyl cellulose, carboxyalkyl cellulose, sodium carboxymethyl cellulose, acrylic resin, or a combination thereof.

In one embodiment, the weight percentage of the carbon material is between 0.3% and 0.6%.

In one embodiment, the solvent comprises water, ethanol, isopropanol, N-methylpyrrolidone, or a combination thereof.

In one embodiment, when the carbon material comprises the combination of the carbon nanotube and the graphene, a ratio of the weight percentages of the carbon nanotube and the graphene is between 99:1 and 3:7.

To achieve the above objective, the present disclosure also provides a plating method for a circuit board. The circuit board comprises at least a through hole, and the plating method utilizes the above-mentioned conductive slurry. The plating method comprises: a coating step for placing the circuit board into the conductive slurry at room temperature for 3 to 10 minutes, thereby forming a layer of the conductive slurry on a surface of the through hole; a first cleaning step for cleaning the circuit board by water at room temperature for 1 to 60 seconds; a first drying step for drying the circuit board at 150 to 200° F. for 5 to 20 minutes; a first micro-etching step for immersing the circuit board in a micro-etching agent at room temperature for 15 to 90 seconds; a second cleaning step for cleaning the circuit board by water at room temperature for 15 to 90 seconds; an anti-oxidation step for performing an anti-oxidation process with the circuit board at 50 to 150° F. for 1 to 5 minutes; a third cleaning step for cleaning the circuit board by water at room temperature for 15 to 90 seconds; a plating step for plating the circuit board at room temperature for 15 seconds to 15 minutes, thereby forming a metal layer on the surface of the through hole; and a second drying step for drying the circuit board at 150 to 250° F. for 1 to 10 minutes.

In one embodiment, between the third cleaning step and the plating step, the plating method further comprises: a second micro-etching step for immersing the circuit board in the micro-etching agent at room temperature for 15 to 90 seconds; and a fourth cleaning step for cleaning the circuit board by water at room temperature for 15 to 90 seconds.

In one embodiment, between the third cleaning step and the second micro-etching step, the plating method further comprises: an acid cleaning step for cleaning the circuit board by an acid cleaning agent at 50 to 150° F. for 1 to 5 minutes; and a fifth cleaning step for cleaning the circuit board by water at room temperature for 15 to 90 seconds.

In one embodiment, between the fourth cleaning step and the plating step, the plating method further comprises: an acid treatment step for immersing the circuit board in a sulfuric acid solution at room temperature for 15 to 90 seconds.

In one embodiment, the metal layer comprises gold, silver, copper, or an alloy thereof.

In one embodiment, the surface of the through hole is formed by a non-conductive material.

In one embodiment, a coverage ratio of the metal layer is between 70% and 100%.

In one embodiment, in the plating step, when the circuit board is plated for 1 to 10 minutes, the coverage ratio of the metal layer is between 95% and 100%.

As mentioned above, the conductive slurry and plating method of this disclosure can improve the conductivity and adhesion of the plated metal layer formed on the surface of the through hole of the circuit board, simplify the plating process, and decrease the manufacturing cost.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a flow chart showing a plating method for a circuit board according to an embodiment of this disclosure;

FIG. 1B is a flow chart showing a plating method for a circuit board according to another embodiment of this disclosure;

FIG. 2A is a schematic diagram of a circuit board used in the plating method of this disclosure;

FIG. 2B is a sectional view of the circuit board of FIG. 2A;

FIG. 2C is a schematic diagram of the circuit board of FIG. 2B after finishing the plating process;

FIG. 3 is a schematic diagram showing the process of utilizing an optical microscope to observe the surface of the through hole; and

FIG. 4 is a schematic diagram showing the results of observing the metal layer formed on the surface of through hole, which is processed by plating with the conductive slurry in the Example I and then treated by a melted tin tank.

### DETAILED DESCRIPTION OF THE DISCLOSURE

The present disclosure will be apparent from the following detailed description, which proceeds with reference to the accompanying drawings, wherein the same references relate to the same elements.

The conductive slurry and plating method of this disclosure can improve the conductivity and adhesion of the plated metal layer, simplify the plating process, and decrease the manufacturing cost.

In this disclosure, a conductive slurry for plating comprises a carbon material, a dispersant, a binder, and a solvent. The carbon material, the dispersant and the binder are uniformly mixed in the solvent. The weight percentage of the carbon material is between 0.1% and 1%, and the carbon material comprises a carbon nanotube, graphene, or a combination thereof. Preferably, the weight percentage of the carbon material is between 0.3% and 0.6%. In one embodiment, the weight percentage of the carbon material is between 0.1% and 1%, and the carbon material comprises carbon nanotubes. Preferably, the weight percentage of the carbon nanotubes is 0.5%. In another embodiment, the weight percentage of the carbon material is between 0.1% and 1%, and the carbon material comprises graphene. Preferably, the weight percentage of the graphene is 0.5%. In another embodiment, the weight percentage of the carbon material is between 0.1% and 1%, and the carbon material comprises a combination of carbon nanotubes and graphene. In this case, a ratio of the weight percentages of the carbon nanotubes and the graphene is between 99:1 and 3:7. Preferably, the ratio of the weight percentages of the carbon nanotubes and the graphene is 1:1. Preferably, the weight percentage of the carbon nanotubes is 0.25%, and the weight percentage of the graphene is 0.25%. Herein, the carbon material is used as a conductive medium for performing the following plating step of the through hole.

In this embodiment, the carbon nanotube is a graphite tube having a nano-level diameter and length-width-height ratio. The inner diameter of the carbon nanotube is between 0.4 nm and tens nm, the outer diameter of the carbon nanotube is between 1 nm and hundreds nm, and the length of the carbon nanotube is between several μm and tens μm. The nanotube is a hollow tube structure formed by curving a single-layer or multilayer of graphite layers. The graphene has the same carbon atom arrangement as the monoatomic layer of graphite, and is a single-layer two-dimensional crystal in which carbon atoms are arranged in a sp² mixed orbital domain in a honeycomb crystal lattice.

In this embodiment, the weight percentage of the dispersant is between 0.1% and 25%. Preferably, the weight percentage of the dispersant is between 0.3% and 1%. The dispersant comprises, for example but not limited to, polyvinyl alcohol, waterborne polyurethane colloid, polyvinyl acetate, polyvinyl ether, polyvinyl chloride, epoxy resin, cresol novolac resin, phenol novolac resin, epichlorohydrin resin, bisphenol resin, phenolic resin, or a combination thereof. Preferably, the dispersant is polyvinyl alcohol, and the weight percentage of the dispersant is between 0.5% and 0.8%. The configuration of the dispersant is to more uniformly mix the carbon material in the solvent.

In this embodiment, the weight percentage of the binder is between 0.1% and 25%. Preferably, the weight percentage of the binder is between 0.3% and 1%. The binder comprises, for example but not limited to, tetrasaccharide, pentose, hexose, maltose, fructose, lactose, cellulose acetate, nitrocellulose, methyl cellulose, carboxymethyl cellulose, glucomannan (d-gluco-d-mannans), milk glucomannan (d-galacto-d-gluco-d-mannans), alkyl cellulose, carboxyalkyl cellulose, sodium carboxymethyl cellulose, acrylic resin, or a combination thereof. Preferably, the binder is sodium carboxymethyl cellulose, and the weight percentage of the binder is between 0.5% and 0.8%. The configuration of the binder can firmly attach the carbon material to the surface of the through hole in the following plating step.

In this embodiment, the solvent comprises, for example but not limited to, water, ethanol, isopropanol, N-methylpyrrolidone, or a combination thereof. In on embodiment, the solvent is water. In another embodiment, the solvent is ethanol. In another embodiment, the solvent is isopropanol. In another embodiment, the solvent is N-methylpyrrolidone. In another embodiment, the solvent comprises water and ethanol. In another embodiment, the solvent comprises water and isopropanol. In another embodiment, the solvent comprises ethanol and isopropanol. In another embodiment, the solvent comprises ethanol and N-methylpyrrolidone. In another embodiment, the solvent comprises isopropanol and N-methylpyrrolidone. In another embodiment, the solvent comprises water, ethanol and isopropanol. In another embodiment, the solvent comprises water, ethanol and N-methylpyrrolidone. In another embodiment, the solvent comprises ethanol, isopropanol and N-methylpyrrolidone. In another embodiment, the solvent comprises water, ethanol, isopropanol and N-methylpyrrolidone. Herein, the configuration of the solvent is to uniformly distribute the carbon material therein.

The preparation of the above-mentioned conductive slurry and the plating method by using the conductive slurry will be described in the following Examples.

### EXAMPLE I

### Preparation of Conductive Slurry

The conductive slurries 1-4 (500 g) are prepared according to the following Table 1. In this Example, the solvent is water, the dispersant is polyvinyl alcohol, and the binder is sodium carboxymethyl cellulose. First, the carbon material, solvent and dispersant are mixed according to the content percentages shown in Table 1. After ultrasonic dispersion (1800 W) for 2 hours, the carbon material is uniformly mixed in water. Then, the binder is added, and the mixture is stirred for 30 minutes to 8 hours (1000-8000 rpm). The conductive slurries 1-4 are prepared for the following Examples.

TABLE 1
content percentages in conductive slurries 1-4

| | Carbon material | Dispersant | Binder | Solvent |
|---|---|---|---|---|
| Sample | (%) | (%) | (%) | (%) |
| Conductive | Carbon nanotube 0.5 | 0.8 | 0.8 | 97.9 |
| slurry 1 | | | | |
| Conductive | Carbon nanotube 0.5 | 0.5 | 0.8 | 98.2 |
| slurry 2 | | | | |
| Conductive | Graphene 0.5 | 0.8 | 0.5 | 98.2 |
| slurry 3 | | | | |
| Conductive | Carbon nanotube 0.25 | 0.5 | 0.8 | 98.2 |
| slurry 4 | Graphene 0.25 | | | |

### EXAMPLE II

### Preparation of Through Hole of Circuit Board

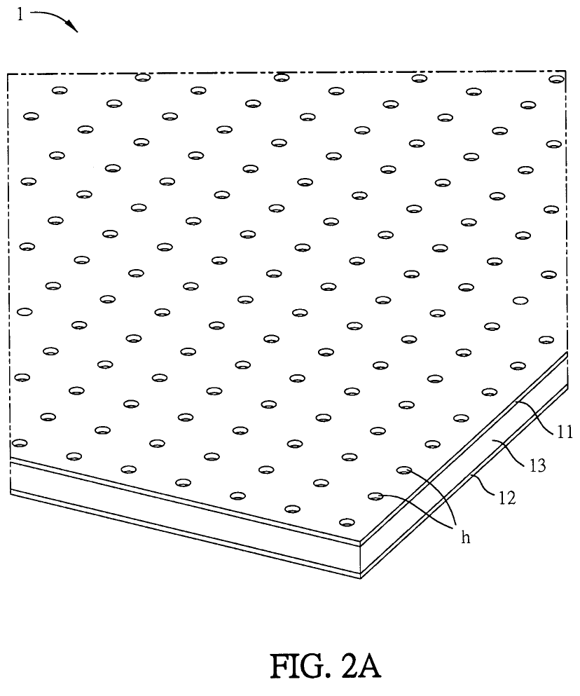

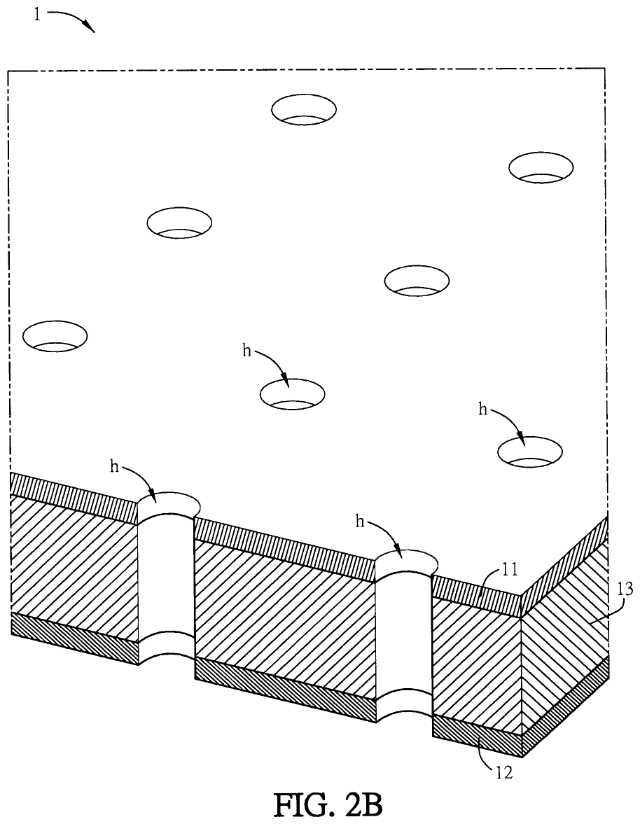

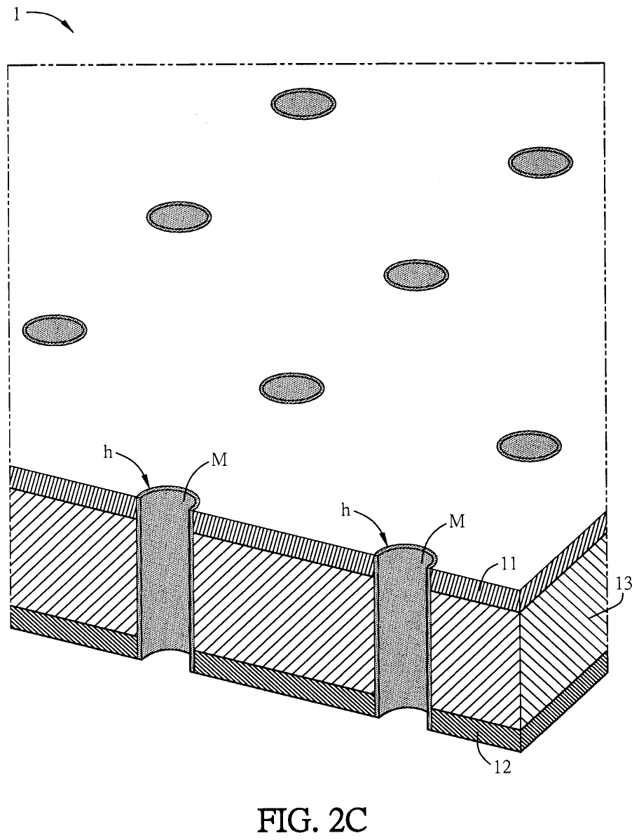

FIG. 2A is a schematic diagram of a circuit board used in the plating method of this disclosure, and FIG. 2B is a sectional view of the circuit board of FIG. 2A. Referring to FIGS. 2A and 2B, a plurality of circuit boards 1 are prepared, and at least one through hole h is formed on each circuit board 1. The circuit board 1 has an upper surface 11, a lower surface 12 and at least a through hole h. The surface of the through hole h is formed by a non-conductive material 13, and the upper surface 11 and the lower surface 12 are conductive layers. The non-conductive material 13 can be a composite material selecting from any of, for example but not limited to, epoxy/glass fiber, polyvinylidene fluoride (PVDF), ceramic, and polyimide (PI). In this embodiment, the non-conductive material 13 is epoxy/glass fiber, and the upper surface 11 and the lower surface 12 are conductive copper layers.

### EXAMPLE III

### A Plating Method for a Circuit Board According to an Embodiment

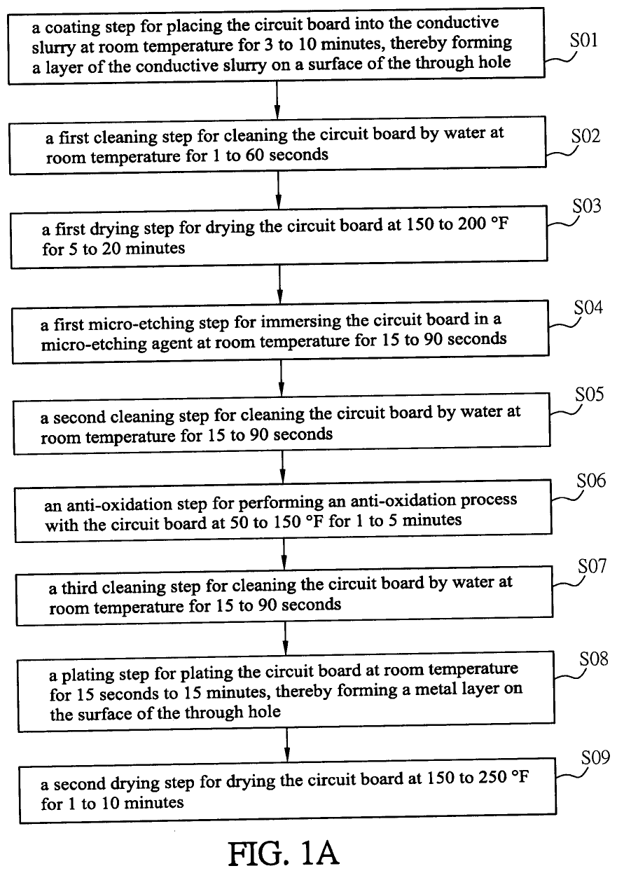

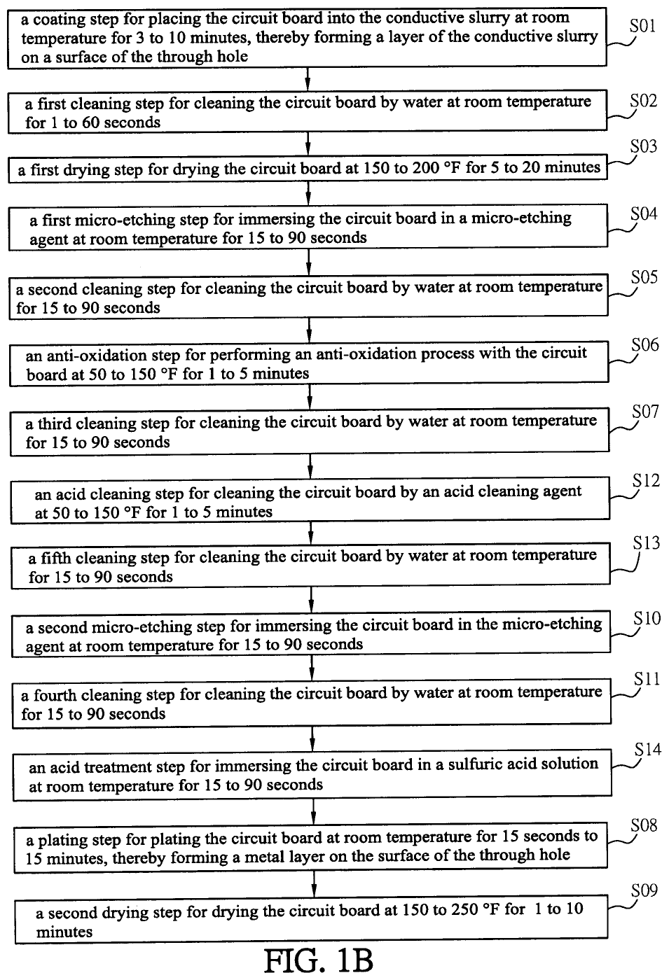

FIG. 1A is a flow chart showing a plating method for a circuit board according to an embodiment of this disclosure, and FIG. 2C is a schematic diagram of the circuit board of FIG. 2B after finishing the plating process. The plating method for a circuit board with using the conductive slurry of this disclosure will be described hereinafter with reference to FIGS. 1A, 2B and 2C. As shown in FIG. 1A, the plating method comprises steps S01 to S09, wherein the step S01 is a coating step, the step S02 is a first cleaning step, the step S03 is a first drying step, the step S04 is a first micro-etching step, the step S05 is a second cleaning step, the step S06 is an anti-oxidation step, the step S07 is a third cleaning step, the step S08 is a plating step, and the step S09 is a second drying step.

The plating method for a circuit board according to an embodiment of this disclosure utilizes the above-mentioned conductive slurry. The steps of the plating method will be described in detail as follow.

In the coating step S01, the circuit board 1 is placed into the conductive slurry at room temperature for 3 to 10 minutes, thereby forming a layer of the conductive slurry on a surface of the through hole h. In the step S01, the upper surface 11, the lower surface 12 and the surface of the through hole h of the circuit board 1 are all coated with a layer of the conductive slurry. Preferably, the circuit board 1 is placed into the conductive slurry for 5 minutes.

In the first cleaning step S02, the circuit board 1 is cleaned by water at room temperature for 1 to 60 seconds. Preferably, the circuit board 1 is cleaned for 30 seconds. In the step S02, the most conductive slurry on the upper surface 11 and the lower surface 12 as well as the redundant conductive slurry on the surface of the through hole h are washed away.

In the first drying step S03, the circuit board 1 is dried at 150 to 200° F. for 5 to 20 minutes, thereby keeping the circuit board 1 in a dried status. Preferably, the circuit board 1 is dried at 190° F. for 15 minutes.

In the first micro-etching step S04, the circuit board 1 is immersed in a micro-etching agent at room temperature for 15 to 90 seconds for removing the residual conductive slurry on the upper surface 11 and the lower surface 12 of the circuit board 1. The micro-etching agent can be, for example but not limited to, hydrogen peroxide solution, sulfuric acid solution, or any of other micro-etching agents used in the conventional plating process. Preferably, the circuit board 1 is immersed in a micro-etching agent (5-30% H₂SO₄ solution) for 60 seconds.

In the second cleaning step S05, the circuit board 1 is cleaned by water at room temperature for 15 to 90 seconds for removing the residual micro-etching agent. Preferably, the circuit board 1 is cleaned for 60 seconds.

In the anti-oxidation step S06, an anti-oxidation process is performed to treat the circuit board 1 at 50 to 150° F. for 1 to 5 minutes, thereby improving the anti-oxidation property of the upper surface 11, the lower surface 12 and the surface of the through hole h of the circuit board 1. Preferably, the anti-oxidation process is performed at 86° F. for 3 minutes. The anti-oxidation agent used in the step S06 can be selected from any of the anti-oxidation agent used in the conventional plating process. In practice, the anti-oxidation agent can be, for example but not limited to, an organic solderability preservatives (e.g. rosin organic solderability preservatives, active resin organic solderability preservatives, or azole organic solderability preservatives). Herein, the azole organic solderability preservatives comprises, for example but not limited to, BTA, IA, SBA, or APA. Preferably, the azole organic solderability preservatives is SBA.

In this third cleaning step S07, the circuit board 1 is cleaned by water at room temperature for 15 to 90 seconds for removing the residual anti-oxidation agent. Preferably, the circuit board 1 is cleaned for 30 seconds.

In the plating step S08, the circuit board 1 is plated at room temperature for 15 seconds to 15 minutes, thereby forming a metal layer M on the surface of the through hole h (see FIG. 2C). In this Example, the coverage ratio of the metal layer M is between 70% and 100%. When the circuit board 1 is plated for between 1 and 10 minutes, the coverage ratio of the metal layer M is between 95% and 100%. Preferably, the metal layer M comprises gold, silver, copper, or an alloy thereof. Preferably, the metal layer M comprises copper or an alloy thereof. Preferably, the plating step is performed under a voltage of −0.18˜0.35V utilizing the AgCl electrode, the plating solution comprises 10% copper ions, and the plating time is 30 seconds or 2 minutes.

Finally, in the second drying step S09, the circuit board 1 is dried at 150 to 250° F. for 1 to 10 minutes, thereby keeping the circuit board 1 in a dried status. Preferably, the circuit board 1 is dried at 190° F. for 5 minutes.

In this Example, the conductive slurries 1-4 are used in the above-mentioned steps S01 to S09, thereby finishing the plating of the surface of the through hole h of the circuit board 1 so as to form a metal layer M of the surface of the through hole h.

### EXAMPLE IV

### A plating Method for a Circuit Board According to Another Embodiment

FIG. 1B is a flow chart showing a plating method for a circuit board according to another embodiment of this disclosure. The plating method for a circuit board with using the conductive slurry according to another embodiment of this disclosure will be described hereinafter with reference to FIGS. 1B, 2B and 2C. As shown in FIG. 1B, except the above-mentioned steps S01 to S09, the plating method further comprises steps S10 to S14 between the steps S07 and S08, wherein the step S10 is a second micro-etching step, the step S11 is a fourth cleaning step, the step S12 is an acid cleaning step, the step S13 is a fifth cleaning step, and the step S14 is an acid treatment step. To be noted, the steps S01 to S09 can be referred to the above embodiment, so the detailed descriptions thereof will be omitted.

In the Example, between the third cleaning step S07 and the plating step S08, the plating method further comprises a second micro-etching step S10 and a fourth cleaning step S11. The second micro-etching step S10 is to immerse the circuit board 1 in the micro-etching agent at room temperature for 15 to 90 seconds. Preferably, the circuit board 1 is immersed in the micro-etching agent for 30 seconds. The fourth cleaning step S11 is to clean the circuit board 1 by water at room temperature for 15 to 90 seconds. Preferably, the circuit board 1 is cleaned by water for 60 seconds. After finishing the step S07, if it is found that the residual conductive slurry on the upper surface 11 and the lower surface 12 of the circuit board 1 is not completely removed, the steps S10 and S11 are performed to completely remove the residual conductive slurry on the upper surface 11 and the lower surface 12 of the circuit board 1.

In this Example, between the third cleaning step S07 and the second micro-etching step S10, the plating method further comprises an acid cleaning step S12 and a fifth cleaning step S13. The acid cleaning step S12 is to clean the circuit board 1 by an acid cleaning agent at 50 to 150° F. for 1 to 5 minutes for removing the oxidant formed on the upper surface 11, the lower surface 12, and the surface of the through hole h of the circuit board 1. Preferably, the circuit board 1 is cleaned by an acid cleaning agent at 115° F. for 3 minutes, and the acid cleaning agent is 5% H₂SO₄ solution. The fifth cleaning step S13 is to clean the circuit board 1 by water at room temperature for 15 to 90 seconds for removing the residual acid cleaning agent. Preferably, the circuit board 1 is cleaned by water for 60 seconds.

In this Example, between the fourth cleaning step S11 and the plating step S08, the plating method further comprises an acid treatment step S14, which is to immerse the circuit board 1 in a sulfuric acid solution at room temperature for 15 to 90 seconds for removing the oxidant formed on the upper surface 11, the lower surface 12, and the surface of the through hole h of the circuit board 1. Preferably, the circuit board 1 is immersed in the sulfuric acid solution for 30 seconds, and the sulfuric acid solution is 10% sulfuric acid solution.

This Example utilizes the conductive slurry of this disclosure to perform the above-mentioned steps S01 to S09 in order, thereby finishing the plating of the surface of the through hole h of the circuit board 1 and forming a metal layer M on the surface of the through hole h. Alternatively, the steps S01 to S07, S10, S11, S08 and S09 are performed in order, or the steps S01 to S07, S12, S13, S10, S11, S08 and S09 are performed in order, or the steps S01 to S07, S12, S13, S10, S11, S14, S08 and S09 are performed in order, thereby improving the conductivity and adhesion of the metal layer M.

### EXAMPLE V

### Plating at Least a Through Hole of the Circuit Board by Conductive Slurries 1-4

The conductive slurries 1-4 obtained in Example I and the circuit board obtained in Example II are prepared to perform the plating process of the through hole of the circuit board. The plating method comprises the steps S01 to S07, S12, S13, S10, S11, S14, S08 and S09 as shown in Example IV, wherein the step S01 is a coating step, the step S02 is a first cleaning step, the step S03 is a first drying step, the step S04 is a first micro-etching step, the step S05 is a second cleaning step, the step S06 is an anti-oxidation step, the step S07 is a third cleaning step, the step S12 is an acid cleaning step, the step S13 is a fifth cleaning step, the step S10 is a second micro-etching step, the step S11 is a fourth cleaning step, the step S14 is an acid treatment step, the step S08 is a plating step, and the step S09 is a second drying step. These steps can be referred to the above embodiments, so the detailed descriptions thereof will be omitted. To be noted, the step S01 is to process different circuit boards by the conductive slurries 1-4, respectively, and the step S08 is to plating the circuit board for 30 seconds or 2 minutes. For example, two circuit boards are coated with the conductive slurry 1, wherein one of the circuit boards is processed by the plating step for 30 seconds, and the other circuit board is processed by the plating step for 2 minutes. The other circuit boards coated with other conductive slurries are processed by the plating step in the same way.

### EXAMPLE VI

### A Plating Method of a Control Circuit Board

The control material (conductive slurry) is a commercial conductive paste (SHADOW® CONDUCTIVE COLLOID 2 (mainly containing carbon black), OMG (Asia) Electronic Chemicals Co., Ltd). The plating method for the circuit board coated with the control material is performed according to the User Guideline of the control material. Except the steps S01 to S14 disclosed in Example V, the additional conditioning and developing steps are needed. The conditioning step is to treat the circuit board by conditioner at 130° F. for 5 minutes, and then to rinse the circuit board at room temperature for 1 minute so as to remove the conditioner. The developing step is to treat the circuit board by a developer at 125° F. for 30 seconds. The conditioning step can provide the surface of the through hole with charges, so that the commercial conductive paste can be easily attached onto the surface of the through hole. The developing step can remove the unfirmly attached commercial conductive paste. In more detailed, for the circuit board coated with the control material, the conditioning step, the step S01, the developing step and the steps S02 to S07, S12, S13, S12, S11, S14, S08 and S09 are performed in order. The step S01 is to coat the circuit board by the commercial conductive paste. The step S08 is to plating the circuit board for 30 seconds or 2 minutes. For example, two circuit boards are coated with the control material, wherein one of the circuit boards is processed by the plating step for 30 seconds, and the other circuit board is processed by the plating step for 2 minutes.

### EXAMPLE VII

### Results of Resistance Test and Coverage Ratio Test after Finishing the Plating of the Through Hole of the Circuit Board

The probes of an electric meter are took to contact the corresponding positions on the upper surface and the lower surface of the circuit boards (obtained in Examples V and VI) to obtain the resistance values, which are record in Table 2.

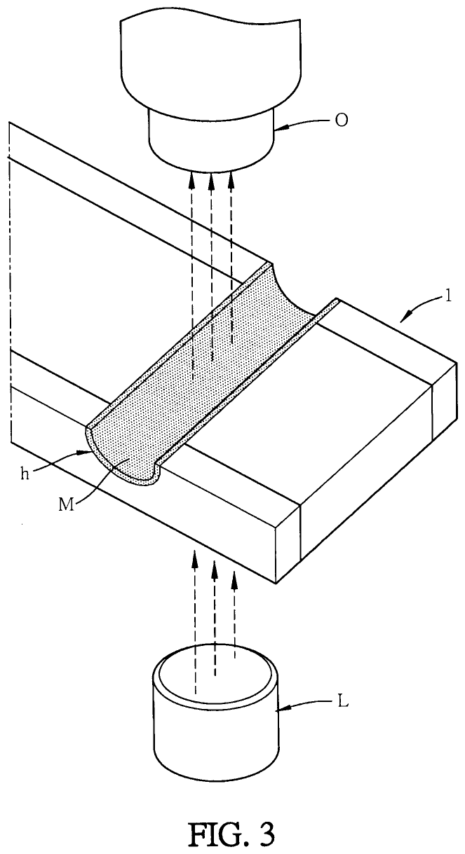

In addition, the coverage ratio test is performed with reference to FIG. 3, wherein FIG. 3 is a schematic diagram showing the process of utilizing an optical microscope to observe the surface of the through hole. The circuit boards 1 obtained in Example V and VI are polished to approach the surface of the through hole h, and then a light source L is provided to emit light in a predetermined direction. If the metal layer M on the through hole h has a high coverage ratio, the light can be blocked so as to present a dark image under the observation of the optical microscope O. If the coverage ratio of the metal layer M is low (the metal layer M has holes), the light spots can be observed. The observation results with respect to the coverage ratio are also record in Table 2.

TABLE 2
resistance values and coverage ratios of the metal layer
on the surface of the through hole of the circuit boards
plated with different conductive slurries

| | Coverage ratio | Coverage ratio | Resistance value |
|---|---|---|---|
| Coated | (%) (plating | (%) (plating | (Ω) (plating |
| material | for 30 s) | for 2 min) | for 2 min) |
| Conductive | 85 | 98 | 10 |
| slurry 1 | | | |
| Conductive | 80 | 96 | 13 |
| slurry 2 | | | |
| Conductive | 80 | 95 | 18 |
| slurry 3 | | | |
| Conductive | 80 | 95 | 15 |
| slurry 4 | | | |
| Control | 55 | 91 | 68 |
| material | | | |

As shown in Table 2, in the case of plating for 30 seconds, the coverage ratios of the metal layers of the circuit boards coated with the conductive slurries 1-4 are between 80% and 85%, and the coverage ratio of the metal layer of the circuit board coated with the control material is only 55%. In the case of plating for 2 minutes, the coverage ratios of the metal layers of the circuit boards coated with the conductive slurries 1-4 are between 95% and 98%, and the coverage ratio of the metal layer of the circuit board coated with the control material is only 91%. In the case for plating for 2 minutes, the resistance values of the circuit boards coated with the conductive slurries 1-4 are between 10Ω and 15Ω, and the resistance value of the circuit board coated with the control material is 68Ω. According to the results of this Example, the circuit boards coated with the conductive slurries of this disclosure have higher coverage ratios of metal layer and lower resistance values than those of the circuit board coated with the control material (commercial conductive slurry), so that the circuit board of this disclosure has better conductivity.

### EXAMPLE VIII

### Results of Adhesion Test for the Metal Layer after Finishing the Plating of the Through Hole of the Circuit Board

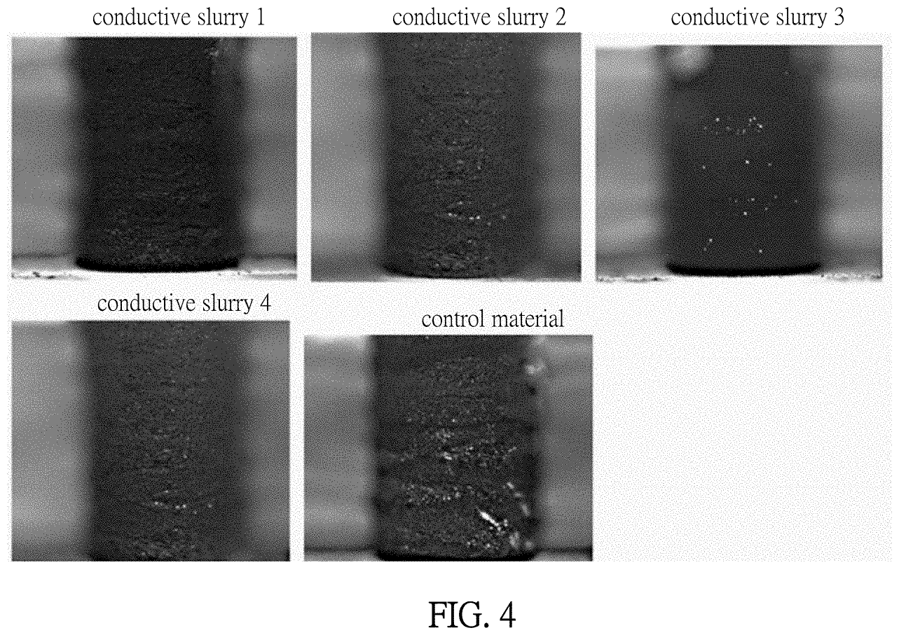

FIG. 4 is a schematic diagram showing the results of observing the metal layer formed on the surface of through hole, which is processed by plating with the conductive slurry in the Example I and then treated by a melted tin tank. Referring to FIG. 3 in view of FIG. 4, the circuit boards of Examples V and VI (plating for 2 minutes) are dipped in a 290° C. melted tin tank for 5 times (1 minute for each dipping). Then, the circuit boards are polished to approach the surface of the through hole h, and then a light source L is provided to emit light in a predetermined direction. The metal layer M formed on the surface of the through hole h is observed with an optical microscope O to determine whether the metal layer M is peeled off or not. If the metal layer M formed on the surface of the through hole h is not peeled off, it can block the light so as to present a dark image under the observation of the optical microscope O. If the metal layer M formed on the surface of the through hole h is (partially) peeled off, the light spots can be observed. The percentage of the light spots in the dark image represents the porosity of the metal layer M. The observation results of FIG. 4 are record in Table 3.

TABLE 3
Porosities of metal layers formed on the surface of
the through hole of the circuit board plated with different
conductive slurries (plating for 2 minutes)

| Coated material | Porosity (%) |
|---|---|
| Conductive slurry 1 | 1 |
| Conductive slurry 2 | 1.3 |
| Conductive slurry 3 | 2 |
| Conductive slurry 4 | 1.67 |
| Control material | 3 |

Referring to Table 3, after plating for 2 minutes and processed by the melted tin tank, the metal layers of the circuit boards coated with the conductive slurries 1-4 have porosities of 1-2%, but the porosity of the circuit board coated with the control material is 3%. The experimental results indicate that, compared with the circuit board coated with the control material (the commercial conductive slurry), the metal layer made by plating the circuit board coated with the conductive slurry of this disclosure has higher adhesion and is not easily peeled off.

Referring to Tables 2 and 3, compared with the circuit board coated with the control material, the metal layer formed on the surface of the through hole of the circuit board of this disclosure has higher coverage ratio, conductivity, and a better adhesion (so the metal layer is not easily peeled off). In addition, the ratio of the carbon material in the conductive slurry of this disclosure is lower, so that the manufacturing cost of the conductive slurry is decreased and the conductive slurry can easily enter the through hole of the circuit board. Moreover, the plating method of this disclosure does not need the conventional conditioning and developing steps, so that this disclosure can simplify plating process and decrease the cost of the plating process with comparing to the conventional plating method.

In summary, the conductive slurry and plating method of this disclosure can improve the conductivity and adhesion of the plated metal layer formed on the surface of the through hole of the circuit board, simplify the plating process, and decrease the manufacturing cost.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A conductive slurry for plating, comprising:
a carbon material;
a dispersant;
a binder; and
a solvent, wherein the carbon material, the dispersant and the binder are uniformly mixed in the solvent, a weight percentage of the carbon material is between 0.1% and 1%, and the carbon material comprises a carbon nanotube, graphene, or a combination thereof.

2. The conductive slurry of claim 1, wherein a weight percentage of the dispersant is between 0.1% and 25%.

3. The conductive slurry of claim 2, wherein the weight percentage of the dispersant is between 0.3% and 1%.

4. The conductive slurry of claim 1, wherein a weight percentage of the binder is between 0.1% and 25%.

5. The conductive slurry of claim 4, wherein the weight percentage of the binder is between 0.3% and 1%.

6. The conductive slurry of claim 1, wherein the dispersant comprises polyvinyl alcohol, waterborne polyurethane colloid, polyvinyl acetate, polyvinyl ether, polyvinyl chloride, epoxy resin, cresol novolac resin, phenol novolac resin, epichlorohydrin resin, bisphenol resin, phenolic resin, or a combination thereof.

7. The conductive slurry of claim 1, wherein the binder comprises tetrasaccharide, pentose, hexose, maltose, fructose, lactose, cellulose acetate, nitrocellulose, methyl cellulose, carboxymethyl cellulose, glucomannan (d-gluco-d-mannans), milk glucomannan (d-galacto-d-gluco-d-mannans), alkyl cellulose, carboxyalkyl cellulose, sodium carboxymethyl cellulose, acrylic resin, or a combination thereof.

8. The conductive slurry of claim 1, wherein the weight percentage of the carbon material is between 0.3% and 0.6%.

9. The conductive slurry of claim 1, wherein the solvent comprises water, ethanol, isopropanol, N-methylpyrrolidone, or a combination thereof.

10. The conductive slurry of claim 1, wherein when the carbon material comprises the combination of the carbon nanotube and the graphene, a ratio of the weight percentages of the carbon nanotube and the graphene is between 99:1 and 3:7.

11. A plating method for a circuit board, wherein the circuit board comprises at least a through hole, and the plating method utilizes the conductive slurry of claim 1, the plating method comprising:
a coating step for placing the circuit board into the conductive slurry at room temperature for 3 to 10 minutes, thereby forming a layer of the conductive slurry on a surface of the through hole;
a first cleaning step for cleaning the circuit board by water at room temperature for 1 to 60 seconds;
a first drying step for drying the circuit board at 150 to 200° F. for 5 to 20 minutes;
a first micro-etching step for immersing the circuit board in a micro-etching agent at room temperature for 15 to 90 seconds;
a second cleaning step for cleaning the circuit board by water at room temperature for 15 to 90 seconds;
an anti-oxidation step for performing an anti-oxidation process with the circuit board at 50 to 150° F. for 1 to 5 minutes;
a third cleaning step for cleaning the circuit board by water at room temperature for 15 to 90 seconds;
a plating step for plating the circuit board at room temperature for 15 seconds to 15 minutes, thereby forming a metal layer on the surface of the through hole; and
a second drying step for drying the circuit board at 150 to 250° F. for 1 to 10 minutes.

12. The plating method of claim 11, between the third cleaning step and the plating step, further comprising:
a second micro-etching step for immersing the circuit board in the micro-etching agent at room temperature for 15 to 90 seconds; and
a fourth cleaning step for cleaning the circuit board by water at room temperature for 15 to 90 seconds.

13. The plating method of claim 12, between the third cleaning step and the second micro-etching step, further comprising:
an acid cleaning step for cleaning the circuit board by an acid cleaning agent at 50 to 150° F. for 1 to 5 minutes; and
a fifth cleaning step for cleaning the circuit board by water at room temperature for 15 to 90 seconds.

14. The plating method of claim 12, between the fourth cleaning step and the plating step, further comprising:
an acid treatment step for immersing the circuit board in a sulfuric acid solution at room temperature for 15 to 90 seconds.

15. The plating method of claim 11, wherein the metal layer comprises gold, silver, copper, or an alloy thereof.

16. The plating method of claim 11, wherein the surface of the through hole is formed by a non-conductive material.

17. The plating method of claim 11, wherein a coverage ratio of the metal layer is between 70% and 100%.

18. The plating method of claim 16, wherein, in the plating step, when the circuit board is plated for 1 to 10 minutes, the coverage ratio of the metal layer is between 95% and 100%.
